(19) United States
(12) Patent Application Publication
(10) Pub. No.: US 2007/0222012 A1
(43) Pub. Date: Sep. 27, 2007

(54) Semiconductor Device

(75) Inventor: Artto Aurola, Espoo (FI)

Correspondence Address: SUGHRUE MION, PLLC, 2100 PENNSYLVANIA AVENUE, N.W., SUITE 800, WASHINGTON, DC, 20037, US

(73) Assignee: ARTTO AUROLA

(21) Appl. No.: 11/596,054

(22) PCT Filed: May 10, 2005
(86) PCT No.: PCT/FI05/50148

§ 371 Date: Jan. 26, 2007

(30) Foreign Application Priority Data
May 11, 2004 (FI) 20045172
Dec. 13, 2004 (FI) 20045475
Feb. 8, 2005 (FI) 20055057

(51) Int. Cl. H01L 27/14

(52) U.S. Cl. 257/430; 257/E27.122

(57) ABSTRACT

A semiconductor device, including a first region (100) of semiconductor material of a first conductivity type. The semiconductor device comprises an elongated spatial element (111, 112, 113) of semiconductor material of a second conductivity type protruding into a first region (100) of semiconductor material of a first conductivity type; and a bias voltage supply adjusted in operation to fully deplete the spatial element from majority carriers of the second conductivity type. A semiconductor device according to the invention is resistant to smear, has a fill factor equal to one, and due to low total capacitance provides improved sensitivity.

### FIELD OF THE INVENTION

The present invention relates to a semiconductor device, and more particularly to a semiconductor device that includes a first region of semiconductor material of a first conductivity type having first surface and a second surface at a defined first distance from the first surface. The semiconductor device can be used for instance in radiation detection devices, solar cells and in electronics including radio frequency (RF) and power electronics.

### BACKGROUND OF THE INVENTION

The operation principle of semiconductor radiation detectors is based on a depleted volume of semiconductor material. Radiation entering the semiconductor and having energy greater than the band gap lifts electrons from the valence band to the conduction band. The missing electrons in the valence band, from now on referred to as holes, and the excess conduction band electrons will soon recombine in areas where the semiconductor material is neutral. Inside a depleted, non-neutral volume, the situation is different: the electron hole pairs are separated by an electric field and there are no free carriers, i.e. holes or conduction band electrons to recombine with. The radiation dose, absorbed in the depleted volume and in regions close to its borders, can be measured by counting the amount of the radiation induced electrons or holes. The measured charge type is later on referred to as the signal charge and opposite charge type is referred to as the secondary charge. The depleted volume is typically created by a reverse biased junction of p and n type semiconductor material. In stead of a reverse biased pn junction a forward biased pn junction can also be used, which is the case in solar cells. The p type semiconductor material is doped with impurity atoms adding excess holes in the valence band, and the n type semiconductor is doped with impurity atoms adding excess electrons in the conduction band. The excess charges of either type are also called as majority carriers and areas doped with n or p type dopants are referred to as areas having n or p type conductivity.

Deep depletion regions are necessary for the detection of deeply penetrating radiation like X-rays, Gamma rays, high-energy particles and photons having energy close to the band gap of the semiconductor. Traditionally such deep depletion regions are formed by introducing doped regions of one conductivity type on at least one surface of a high resistive semiconductor wafer of the other conductivity type and by applying a reverse bias between these differently doped regions in order to deplete the semiconductor wafer. Such structures manufactured on the surfaces of a semiconductor wafer are later on referred to as two-dimensional (2D) structures. The problem with two-dimensional structures is that the reverse bias voltages needed to deplete the wafer is proportional to the square of the thickness of the wafer. Thus very high voltages are necessary to deplete thick wafers. Another problem is that the thicker the wafers are, the more smear is in the images, i.e. the more the radiation induced signal charge cloud spreads before it is collected.

U.S. Pat. No. 6,259,085 discloses a buried channel CCD structure where regions of p type semiconductor material (p type buried channel) are arranged into an area of n type semiconductor material (n type wafer). The structure is made with a 2D process and in operation it is fully depleted. As typical to 2D structures, the form of the p type area is flat, which means that the shortest horizontal dimension of the protrusion is considerably less than its vertical dimension. If the device is manufactured on a thick wafer, a high bias voltage is needed to deplete the structure, and smear is resulted in the images.

In order to address the afore mentioned problems, three dimensional (3D) structures comprising elements that protrude deep into a semiconductor wafer, have been introduced. The distance between the protruding elements can be less than the thickness of the wafer, thus enabling full depletion of the wafer with a relatively low applied bias voltage. The 3D potential profile inside the wafer due to the 3D structures reduces the smear effect.

U.S. Pat. No. 5,981,988 discloses a 3D charge coupled device (3D-CCD). This structure is manufactured by making holes to a semiconductor wafer and by covering the walls of the holes by an isolator layer. On top of the isolator layer is deposited a conductor layer which forms the 3D gates of the 3D-CCD. However, the 3D isolator and conductor layers are not sensitive to radiation, i.e. the ratio of the radiation sensitive area of one pixel and the total pixel area (fill factor) is less than one. In addition, the area of the semiconductor insulator interface is large. This is a problem, as a lot of dark current is generated at the semiconductor isolator interface during signal transport phase increasing significantly the noise of the device.

U.S. Pat. Nos. 5,889,313 and 6,204,087 disclose a 3D electrode structure where holes are made to a high resistive wafer. Some of the holes are filled with highly doped n type semiconductor material, and the rest of the holes are filled with highly doped p type material. Due to the high dopant concentration, these structures act as electrodes, and are hereinafter referred to as 3D electrodes or rods. The distance between the n and p type 3D electrodes can be made very short which results, beside the reduced depletion voltage and the reduced smear effect, also in very fast signal rise times and reduced influence of the type inversion of the wafer (from n to p type) due to very intense radiation. The disclosed problem is designed for high energy physics experiments, where fast detector operation due to fast signal rise times and the improved tolerance to radiation damage due to the reduced influence of the type inversion of the wafer are important design criteria. To exploit the fast operation speed complicated electronics is required to monitor individual pixels simultaneously.

However, in many radiation detector applications a radiation image pattern is measured after an integration period and thus the fast signal rise time is substantially irrelevant. The charge packets collected by pixels can be read one by one, which requires only simple readout electronics. Additionally, good radiation tolerance is not that crucial when the intensity of radiation is relatively low, or if the damage potentially caused by the observed radiation type is relatively small. In such applications, the electrode nature of the 3D rods is, however, a drawback. The capacitance of the rods is inversely proportional to the distance between the rods and proportional to the surface area of the neutral volume of the rods, which is essentially the same as the surface area of the rods. Since the distance between the rods is small and the surface area of the rods is large, the capacitance of the 3D electrode is relatively high. The high capacitance leads to low sensitivity of the device. For instance, if the 3D electrodes are connected to gates of field effect transistors (FET), the change in current running through the FET caused by the signal charge is relatively small due to the large capacitance of the 3D electrode. An issue is also that the relatively high capacitance between the 3D electrodes may result crosstalk in nearby 3D electrodes. Another aspect of the electrode nature of 3D rods is that the radiation generated charge packets cannot be transported from one location to another, because the signal charges mix with the charges present in the neutral parts of the 3D electrodes and they cannot be appropriately separated later on. This aspect means that 3D electrodes are only applicable to active pixel sensor (APS) configurations, but not to charge transport device (CTD) configurations. A further problem associated with the electrode nature of the 3D rods is that part of a signal created by radiation absorbed inside the 3D electrodes is lost by recombination inside the neutral, highly doped 3D electrodes, reducing the quantum efficiency and degrading the energy resolution of the device.

The capacitances of for example transistors in integrated circuits (IC) can be reduced by manufacturing the transistors on high resistivity wafers and by depleting the wafers. Smaller capacitances lead to a higher operation speed of the transistors and of other electronic structures which is important especially in RF electronics. Relatively high voltages are, however, needed to deplete such wafers leading to high power consumption which is a problem in portable devices. Very high voltages present in power electronics result high maximal electric field values limiting the voltage handling capacity of the devices.

### BRIEF DESCRIPTION OF THE INVENTION

The object of this invention is to provide a smear resistant radiation detection device with improved sensitivity, where the structures within the semiconductor wafer contain a minimum amount of material insensitive to radiation. A further object of the invention is to provide an improved radiation detection device which is applicable to both CTD and APS configurations. A further object of the invention is also to provide means to reduce the power consumption to increase the operation speed and to improve the voltage handling capacity of electronics.

The objects of the invention are achieved by a radiation detection device of claim 1, characterized by the radiation detection device comprising an elongated spatial element of semiconductor material of a second conductivity type protruding into a first region of semiconductor material of a first conductivity type; and a bias voltage supply adjusted in operation to fully deplete the elongated spatial element from majority carriers of the second conductivity type. In this embodiment, the first region of semiconductor material of the first conductivity type is referred to as the substrate. The thickness of the spatial element and the dopant concentrations of the spatial element and of the substrate, are adjusted so that the spatial element is fully depleted when the voltage supply is biased appropriately. Beneficially, the distance between the spatial elements is adjusted to a level that allows the substrate and the spatial elements to be depleted approximately at the same applied bias voltage. The preferred embodiments of the invention are disclosed in the dependent claims.

The invention is based on the idea of utilizing elongated spatial elements protruding into the semiconductor substrate. The elongated spatial elements are fully depleted, i.e. have substantially no neutral areas inside. Advantageously, the substrate may also became fully depleted. The total capacitance of the invented structure is very low, comparable to a traditional fully depleted detector, and therefore much lower than the capacitance of the conventional 3D electrode structures. The low capacitance leads to improved detec- tion sensitivity of the device. On the other hand, the voltage required to deplete the invented structure is comparable to the 3D electrode structure, and therefore much lower than in a traditional fully depleted detectors. The spatial elements create inside the device a 3D potential profile that reduces the smear effect to a degree comparable to the 3D electrode structure, which is much less than in conventional fully depleted detectors. In addition, the electron hole pairs created by radiation inside the depleted spatial elements are separated immediately by an electric field, i.e. inside the spatial elements there are substantially no neutral areas, where part of the signal would be lost by recombination. The depleted nature of the spatial elements allows CTD operation for radiation generated charge carriers of the second conductivity type. If the substrate is also fully depleted, CTD operation for radiation generated charge carriers of the first conductivity type is enabled. Advantageously, a potential gradient may be formed inside the depleted spatial element and possibly inside a fully depleted substrate to transport the signal charges towards the surface of the wafer where the signal charge is detected.

The power consumption of electronics can be reduced, and the operation speed, and the voltage handling capacity of electronics can be increased by substantially depleting the elongated spatial elements and benefi- cially also the substrate. The invented structure can be depleted with a considerably smaller bias voltage than depleting a corresponding wafer having no spatial elements. It is even possible to deplete the substrate and the spatial elements with substantially zero bias voltage.

### BRIEF DESCRIPTION OF THE DRAWINGS

In the following the invention will be described in greater detail by means of some embodiments with reference to the attached drawings, in which

FIG. 1 illustrates an embodiment of the semiconductor device according to the present invention;

FIG. 2 illustrates an alternative configuration of the semiconductor device;

FIG. 3 illustrates a top view of the first surface 101 of FIGS. 1 and 2;

FIG. 4 illustrates an embodiment of a buried channel charge coupled device applying the invented structure;

FIG. 5A, 5B and 5C illustrate the variation of the electron potential energy in the charge-coupled device of FIG. 4;

FIG. 6 illustrates an embodiment of an active pixel sensor com- prising the invented structure;

FIG. 7 illustrates another embodiment of an active pixel sensor applying the invented structure;

FIG. 8 illustrates another embodiment of a buried channel charge coupled device applying the invented structure;

FIG. 9 illustrates an embodiment of yet another active pixel sensor applying the invented structure.

FIG. 10 illustrates a cavity that has been processed in to a semiconductor substrate of the first conductivity type.; and FIGS. 11A-11C illustrate the electron potential function on the line 1007 of FIG. 10.

### DETAILED DESCRIPTION OF THE INVENTION

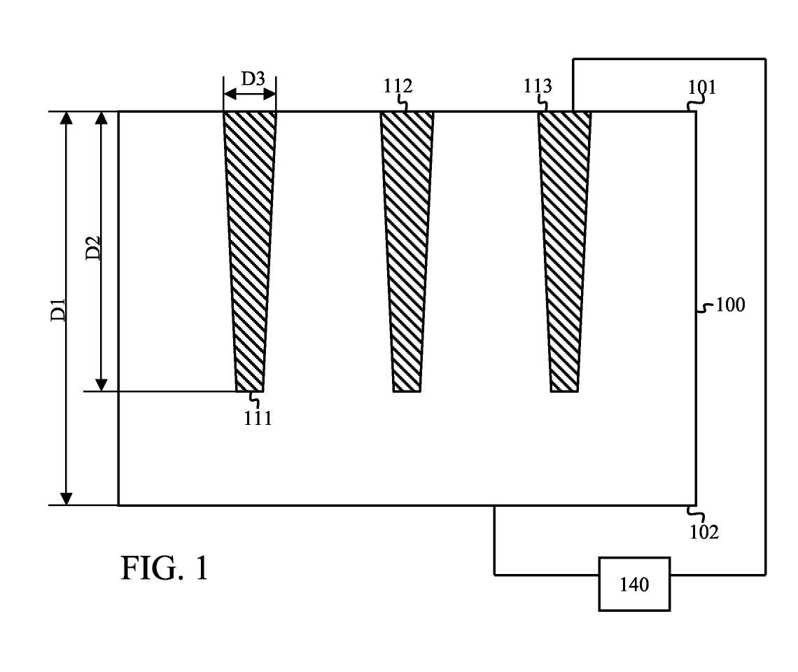

FIG. 1 illustrates an embodiment of the radiation detection device according to the present invention. The device comprises a first region of a first conductivity type, hereinafter referred to as semiconductor substrate 100. The semiconductor substrate 100 has a first surface 101 and a second surface 102, and a first distance D1 between these surfaces. The first surface 101 corresponds to part of the boundary of the semiconductor substrate 100, said part extending to two dimensions of the radiation detection device. In FIG. 1, the first surface 101 corresponds to the front surface, and extends to two dimensions, hereinafter regarded as the horizontal directions. In FIG. 1, the second surface 102 runs parallel to the first surface, corresponds to the back surface, and extends from the first surface to a perpendicular dimension, hereinafter regarded as the vertical direction.

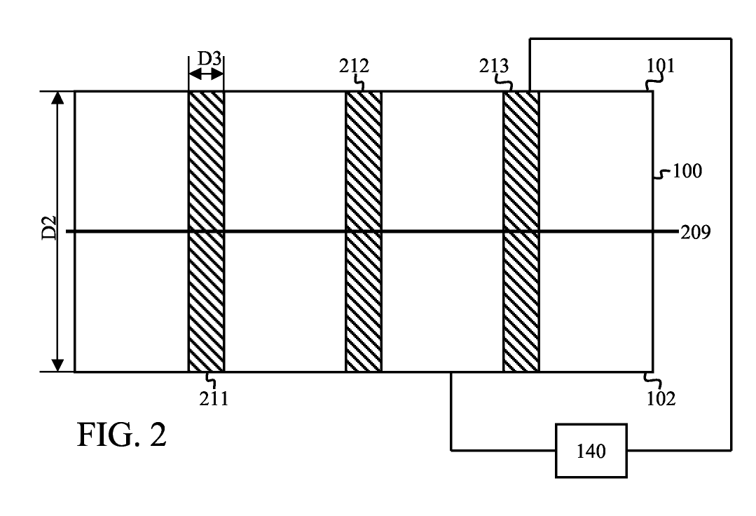

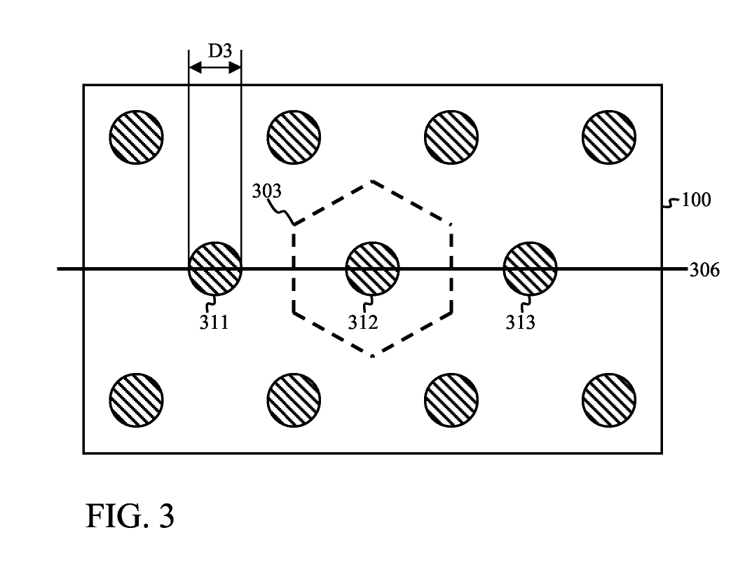

In addition, the device comprises elongated spatial elements 111, 112, 113 of second conductivity type. The elongated spatial elements 111, 112, 113 protrude to a second distance D2 from the first surface 101 into the semiconductor substrate 100. FIG. 2 illustrates an alternative configuration, where D1=D2, meaning that the elongated spatial elements 211, 212 and 213 protrude completely through the semiconductor substrate 100. FIG. 3 illustrates a top view of the first surface 101 of FIGS. 1 and 2. The spatial elements 311, 312 and 313 of FIG. 3 correspond to spatial elements 111, 112 and 113 of FIG. 1, orto spatial elements 211, 212, and 213 of FIG. 2. The area inside the box 303 corresponds to the area of one pixel in this embodiment. The line 306 presents the image planes of FIGS. 1 and 2. The distance D3 illustrates the smallest dimension of the spatial element at the first surface 101. In FIG. 3, the footprint of the elongated spatial element is a circle, whereby the smallest dimension of the spatial element in the front surface cor- responds to the diameter of the circle.

In FIGS. 1 and 2, the spatial elements are shown as elongated columns that protrude from the horizontal front surface into the substrate. The elongated form of the spatial element means that smallest dimension D3 of the spatial element at the first surface is less than the dimension of the spatial element that corresponds to the depth of the protrusion D2 into the semiconductor substrate 100. In FIGS. 1 and 2 the latter dimension corresponds to the second distance D2, i.e. the vertical dimension of the spatial element is D2, whereby the equation becomes D3<D2. Typically the vertical dimension is considerably bigger, so advantageously the inequality D2>2×D3 may be used. Most advantageously the smallest horizontal dimension of the spatial element is far smaller than the vertical dimension of the spatial element, a situation which is presented in FIGS. 1, 2, 4, 6 to 9. Inequalities can be listed in order of preference: D2>5×D3, D2>4×D3, D2>3×D3, D2>2×D3, D2>D3, where the first one is the most beneficial inequality. The level of protrusion may vary according to the application but typically the end of the spatial element should extend to a distance of at least 5 μm.

According to the invention, the spatial elements need to be depleted from the majority carriers of the second conductivity type. For this purpose, the embodied radiation detection device is provided with a voltage source 140. The purpose of the voltage source 140 is to reverse bias the pn junction between the substrate and the spatial elements in such an extent that the spatial elements become fully depleted. The required depletion voltages are discussed in more detail later in the document.

The radiation detection devices of FIGS. 1 to 3 can be manufactured, for example, by dry etching (e.g. plasma etch, time multiplexed plasma etch, reactive ion etch RIE) or by laser drilling holes in to a semiconductor wafer of the first conductivity type. For instance an ultra violet (UV) laser (like eximer laser) operating in pulsed mode could be used in vacuum condition. The holes can be of any depth and they may penetrate the whole wafer. If necessary the walls of the holes and possibly the surfaces of the wafer may be subsequently smoothed by wet etching. One can also polish the surfaces of the wafer by chemical mechanical polishing (CMP). The holes are filled by depositing semiconducting material of the second conductivity type using, for example, atomic layer deposition (ALD) also known as atomic layer epitaxy (ALE), liquid phase epitaxy, chemical vapor deposition (CVD) (e.g. low pressure vapor deposition LPCVD), or another corresponding method. After the deposition, a wet etch step may be performed, after which the surfaces of the wafer may be CMP polished.

In the case where the wafer and the spatial elements are comprised of different preferably lattice matched semiconductor materials forming a heterostructure and liquid phase epitaxy is used as the manufacturing method, the melting point of the wafer material should be higher than the melting point of the material forming the spatial elements. One could use, for instance, a wafer where the holes penetrate the whole wafer, and a liquid phase process having a temperature higher than the melting point of the material forming the spatial elements and lower than the melting point of the wafer material. Then, for example, capillary phenomenon can be utilized to fill the holes in the wafer with melted material forming the spatial elements. When the holes are completely filled the process temperature can be lowered below the melting point of the material forming the spatial elements.

The substrate and the elongated spatial elements may form an abrupt heterostructure. Depending on the electron affinities, the Fermi levels, and the bandgaps of the afore said materials, a 2D quantum well for charges of either conductivity type may be formed at the hetero interface. This 2D quantum well will be depleted during operation as well as the spatial elements. If there is an electron potential gradient in the fully depleted spatial element there will also be an electron potential gradient in the depleted 2D quantum well pointing in the same direction than the electron potential gradient in the spatial element. Thus part of the radiation generated charges of either conductivity type may also be transported in the 2D quantum well. In spite of this fact the operation principle of the device remains exactly the same. The 2D quantum well can be avoided, if desired, by introducing a transition region at the interface where the substrate material changes smoothly to the material forming the spatial elements.

It should be noted that the structure in FIG. 2 can be manufactured from the structure presented in FIG. 1 by grinding the backside of the wafer. While doing this the front side of the wafer may be attached to a support wafer. Alternatively, one can use through out the process wafers where the holes penetrate the whole wafer. Respectively the structure in FIG. 1 can be manufactured from the structure presented in FIG. 2 by depositing semiconductor material of the first conductivity type on top of the back surface of the structure in FIG. 2. The semiconductor materials forming the spatial elements and the wafer can be single crystalline, polycrystalline or amorphous materials. The invented structure could be formed of semiconductor materials like Si, Ge, GaAs, CdTe, CdZnTe, HgI₂, PbI₂ and Se and possibly of associated compound semiconductors having two, three, four, five, six or even more different compound atoms. The choice of the materials is, however, not limited to the afore mentioned list.

The diameter and the dopant concentration of the elongated spatial elements, and the doping of the substrate are adjusted in such a way that the spatial elements can be depleted with a relatively low reverse bias voltage applied between the substrate and the spatial elements. Advantageously, the reverse bias may be adjusted such that the substrate also becomes fully depleted. The distance between the spatial elements may even be configured such that the spatial elements and the substrate become depleted approximately at the same applied bias voltage. This may be implemented, for example, by adjusting a defined horizontal cross-section of the radiation detection device at a depth anywhere between zero and D2 to contain approximately the same amount of both types of dopant atoms. Such a cross-section is represented by the line 209 in FIG. 2.

Advantageously, a sub-area that belongs to one pixel (303) in the defined horizontal cross-section may be adjusted to contain approximately the same amount of both types of dopant atoms. If the defined sub-area that belongs to one pixel has more dopant atoms of the first type than of the second type, the spatial elements will become depleted before the substrate. For example, when high quality high resistive substrate is used, the minority carrier lifetime in the neutral parts of the substrate is high and the radiation generated charge carriers of the second conductivity type are very likely collected by the depletion regions surrounding the fully depleted spatial elements. In such a case, the quantum efficiency is not essentially reduced. On the other hand, if the defined sub-area that belongs to one pixel has more dopant atoms of the second type than of the first type, the substrate will become depleted before the spatial elements. In this case unnecessarily high bias voltages are needed to deplete deeply protruding spatial elements. The 3D electrode structure corresponds to this situation.

When a bias voltage greater than the depletion voltage of the spatial elements is applied, a field directed along the spatial elements is created inside the depleted spatial elements transporting charge carriers of the second conductivity type towards the front side of the device. When a bias voltage greater than the depletion voltage of both the spatial elements and the substrate between the spatial elements is used, a field is created inside the depleted substrate transporting the charge carriers of the first conductivity type towards the substrate contact. There are several additional methods to create the aforementioned transporting field within the fully depleted spatial elements and possibly inside the depleted substrate. One of the methods is to decrease the horizontal cross-section area of the spatial elements with relation to the depth of the protrusion (see FIG. 1). Another method is to vary the dopant concentration in the spatial elements in such a way that the dopant concentration decreases as a function of the depth of the spatial elements, i.e. the spatial element is more heavily doped at the front surface of the substrate, and less heavily doped at the end next to the back surface of the substrate. A further method is to vary the dopant concentration of the substrate in such a manner that the dopant concentration of the substrate is lowest at the front surface and highest at the back surface. One can also use any combination of the four afore mentioned methods.

As discussed above, the desired depletion effect is a result of a functional combination of the dopant concentration levels of the substrate 100 and the spatial elements 111, 112, 113, and of the applied reverse bias voltage between the substrate 100 and the spatial elements 111, 112, 113. As an example, in a general one-dimensional case the dimensions of the depletion regions are derivable from:

$$\begin{matrix}{d}_{n} = \sqrt{\frac{2 ɛ {ɛ}_{0} {N}_{A} ( V + {V}_{bi} )}{q {N}_{D} ( {N}_{A} + {N}_{D} )}} , & ( 1 ) \\ {d}_{p} = \sqrt{\frac{2 ɛ {ɛ}_{0} {N}_{D} ( V + {V}_{bi} )}{q {N}_{A} ( {N}_{A} + {N}_{D} )}} , & ( 2 )\end{matrix}$$

where dₙ and dₚ are the depths of the depletion region in n and p type materials. Parameter ε is the relative permittivity of the material, 68 ₀ is the permittivity of a vacuum, N_{A} and N_{D} are the net dopant concentrations of the p and n type materials and q is the elementary charge. V is the reverse bias voltage, and V_{bi} is the built in voltage of the form

$${V}_{bi} = \frac{k T}{q} ln ( \frac{{N}_{A} {N}_{D}}{{n}_{i}^{2}} ) , \qquad ( 3 )$$

where k is the Boltzmann constant, T is the temperature, and nᵢ is the intrinsic carrier concentration in temperature T. In silicon, at 300 K, nᵢ is approximately 1,45×10¹⁰cm⁻³.

In practice, to implement the desired depletion to the spatial element the dopant concentration of the spatial element needs to be adjusted to values less than 10¹⁷cm⁻³. Otherwise, extraordinary thin spatial elements should be used in order to reach the desired depletion effect of the spatial elements at a reasonable voltage. Correspondingly, the reverse bias voltage applied between the spatial elements and the substrate needs to be adjusted according to the half-maximum thickness of the spatial element as outlined in equations (1) and (2). Below some examples of possible dopant concentration ranges and related bias voltages according to a one-dimensional approximation.
N_{D}=N_{A}=10¹⁴cm⁻³: 1)
dₙ=dₚ=2,6 μm×\sqrt{V+0,43}
V=0V: dₙ=dₚ=1.7 μm
V=10V: dₙ=dₚ=8.3 μm
V=20V: dₙ=dₚ=12 μm
V=50V: dₙ=dₚ=18 μm
V=100V: dₙ=dₚ=26 μm

Consequently, if the maximum thickness of an elongate n or p type spatial element is 15 μm, it can be depleted with a 10V bias voltage. Beneficially the distance between adjacent spatial elements from the center point to center point should be 30 μm in order for the spatial elements and the substrate to be depleted at approximately the same applied bias. If it is not necessary to deplete the substrate, the distance between the spatial elements can be higher than 30 μm. However, it is not beneficial to have a shorter distance than 30 μm between the spatial elements because then high bias voltages are required to deplete the spatial elements fully. The depletion of a 50 μm thick n or p type spatial element requires 100V bias.

2) N_{D} = 10¹⁶cm⁻³, N_{A} = 10¹⁴cm⁻³:

| | |
|---|---|
| dₙ = 0.036 μm × \sqrt{V + 0.55} , | dₚ = 3.6 μm × \sqrt{V + 0.55} |

| | | |
|---|---|---|
| V = 0 V: | dₙ = 0.027 μm, | dₚ = 2.7 μm |
| V = 10 V: | dₙ = 0.12 μm, | dₚ = 12 μm |
| V = 20 V: | dₙ = 0.16 μm, | dₚ = 16 μm |
| V = 50 V: | dₙ = 0.26 μm, | dₚ = 26 μm |
| V = 100 V: | dₙ = 0.36 μm, | dₚ = 36 μm |

In this case 0,5 μm thick n type or 50 μm thick p type spatial element can be depleted with 50V bias.
N_{D}=N_{A}=10¹⁶cm⁻³: 3)
dₙ=dₚ=0.26 μm×\sqrt{V+0.66}
V=0V: dₙ=dₚ=0.21 μm
V=10V: dₙ=dₚ=0.84 μm
V=20V: dₙ=dₚ=1.2 μm
V=50V: dₙ=dₚ=1.8 μm
V=100V: dₙ=dₚ=2.6 μm

In this case 1.5 μm thick n or p type spatial elements can be depleted with 10V bias voltage.

4) N_{D} = 10¹⁴cm⁻³, N_{A} = 10¹⁶cm⁻³:

| | |
|---|---|
| dₙ = 3.6 μm × \sqrt{V + 0.55} , | dₚ = 0.036 μm × \sqrt{V + 0.55} |

| | | |
|---|---|---|
| V = 0 V: | dₙ = 2.7 μm | dₚ = 0.027 μm, |
| V = 10 V: | dₙ = 12 μm | dₚ = 0.12 μm, |
| V = 20 V: | dₙ = 16 μm | dₚ = 0.16 μm, |
| V = 50 V: | dₙ = 26 μm | dₚ = 0.26 μm, |
| V = 100 V: | dₙ = 36 μm | dₚ = 0.36 μm, |

In this case a 5 μm thick n type spatial element can be depleted with 0V bias voltage. 50 μm thick n type or 0.5 μm thick p type spatial elements can be depleted with 50V bias voltage.

5) N_{D} = 10¹⁴cm⁻³, N_{A} = 10¹²cm⁻³:

| | |
|---|---|
| dₙ = 0.36 μm × \sqrt{V + 0.32} , | dₚ = 36 μm × \sqrt{V + 0.32} |

| | | |
|---|---|---|
| V = 0 V: | dₙ = 0.20 μm, | dₚ = 20 μm |
| V = 10 V: | dₙ = 1.2 μm, | dₚ = 120 μm |
| V = 20 V: | dₙ = 1.6 μm, | dₚ = 160 μm |
| V = 50 V: | dₙ = 2.6 μm, | dₚ = 260 μm |
| V = 100 V: | dₙ = 3.6 μm, | dₚ = 360 μm |

This combination allows 3.2 μm thick n type spatial element to be depleted with 20V bias voltage. Beneficially the distance between adjacent spatial elements from center point to center point is 323 μm.

It can be seen that the spatial elements have dopant concentrations that are below the level of electrode dopant concentrations that are typically higher than 10¹⁸cm⁻³. In general dopant concentrations less than 10¹⁷cm⁻³ are applicable, otherwise the spatial elements need to be extraordinarily thin to reach the full depletion of the spatial elements. In the prior art solutions the 3D electrodes have a dopant concentration around 10¹⁸cm⁻³ and the substrate has a dopant concentration around 10¹²cm⁻³. Using the one-dimensional approximation one finds out easily that the depletion of a 5 μm thick 3D electrode requires a bias voltage of the order of 5×10⁹V. It is clear that with such dopant concentration levels the depletion of the spatial elements from majority carriers is not possible. As a summary one can state that a semiconductor region having a very high dopant concentration (marked as n+or p+) has a high conductivity, it is practically impossible to deplete, and is thus neutral inside. Such a region behaves essentially as a conductor, i.e. as an electrode which can be biased or floating.

The embodiments of the invention presented in FIGS. 1 to 2 can be incorporated to a variety of different radiation detection configurations where the absorbed radiation dose is transformed into signal charges using a reverse biased configuration or a forward biased semiconductor configuration.

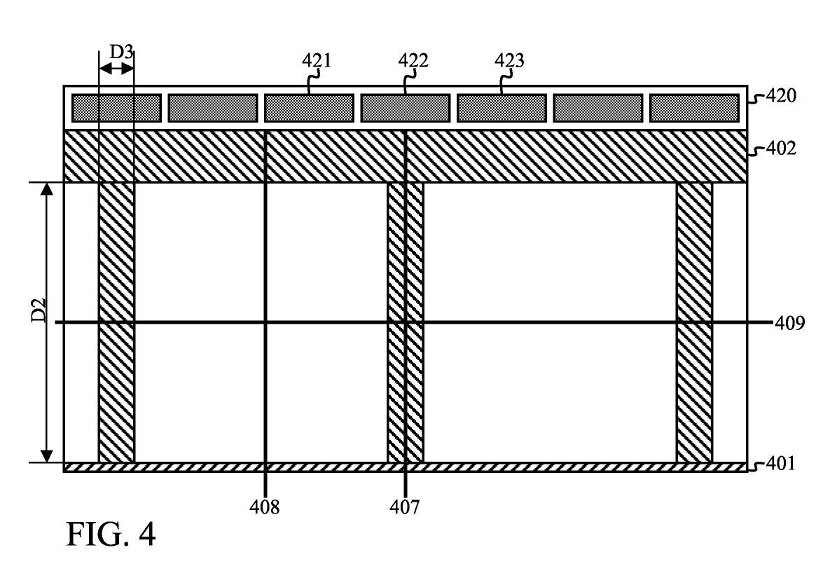

These may be manufactured, for instance, by adding different types of implants and layers on top of the front and back surfaces of the aforesaid devices. As an example of such configurations, FIG. 4 illustrates a buried channel CCD comprising a radiation detection device according to an embodiment of the invention. The buried channel is formed in the buried channel layer 402 of the second conductivity type, which can be formed, for instance, by implantation or by epitaxial growth. On the backside of the device is a highly doped layer 401 of the first type of conductivity, and on the front side is an isolator layer 420. Inside the isolator layer are the gates. In FIG. 4, three gates, marked as 421, 422 and 423, belong to one pixel. In FIG. 4, the channel stop structures (usually areas of the first conductivity type on the front side) are floating or appropriately biased. From now on it is assumed that the first type of conductivity refers to p type conductivity and that the second type of conductivity refers to n type conductivity, but for a person skilled in the art it is clear that the types can be reversed without deviating from the scope of protection. According to the invention, during operation appropriate voltages are connected to a buried channel layer 402 contact doped region to the back layer 401 and to the gates to fully deplete the spatial elements. Preferably, but not mandatorily, also the substrate is fully depleted during operation.

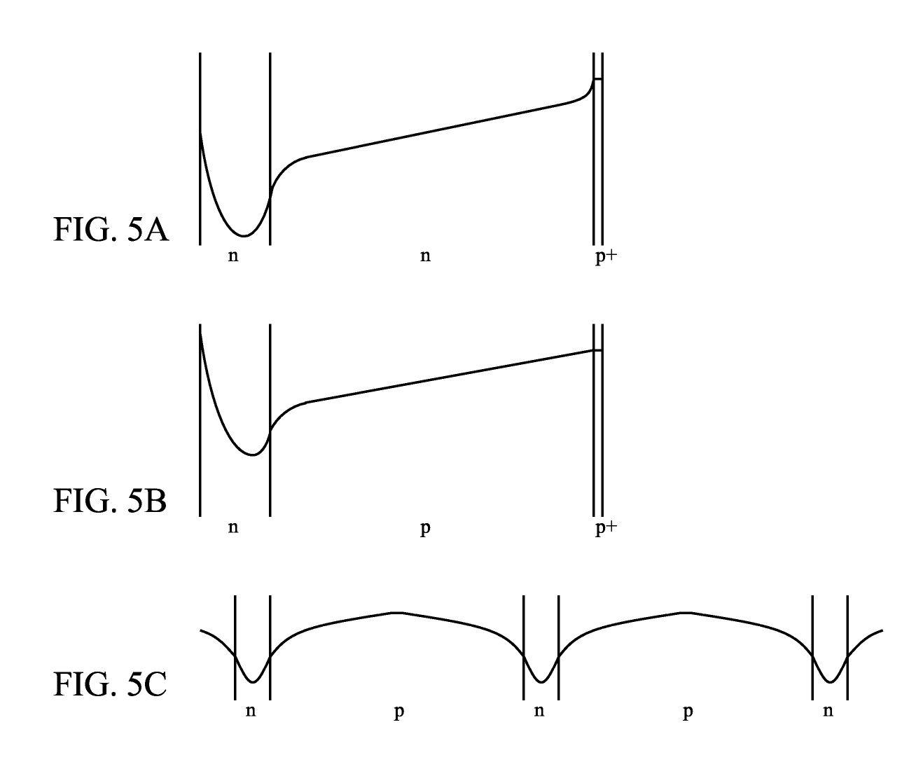

In the following, the operational principle of the embodied radiation detection device of FIG. 4 is explained by means of curves illustrating the electron potential energies on lines 407, 408 and 409. These curves are shown in FIGS. 5A, 5B and 5C. Straight horizontal lines in the functions correspond to neutral areas in the semiconductor material; the rest of the semiconductor material is depleted. It can be seen from FIGS. 5A, 5B and 5C that here the only neutral area is the heavily doped back layer 401. The electron potential energy along the spatial element (along line 407, FIG. 5A) has a gradient transporting the electrons which are in this embodiment the signal charges to a potential minimum within the buried layer. The electron potential energy along the line 408 between the spatial elements is presented in FIG. 5B. The holes which are in this case the secondary charges move due to the electron potential energy gradient into an opposite direction than the electrons, which means that the holes in FIG. 5B move towards the backside of the device to be collected by the layer 401. A considerable portion of the electron potential energy function in FIGS. 5A and 5B is presented by a straight line which corresponds to the case when the cross-section presented by the line 409 has an equal amount of dopant atoms of both conductivity type, i.e. the field never reaches a critical value regardless how thick the substrate is. The electron potential energy along the line 409 is presented in FIG. 5C. The curve in FIG. 5C has a number of potential energy minima, each corresponding to the spatial elements. This explains the reduction in the smear effect; the signal charge electrons are collected by these potential energy minima and do not spread due to the electric repulsion effect. The secondary charge holes are collected by the potential energy maxima presented in FIG. 5C.

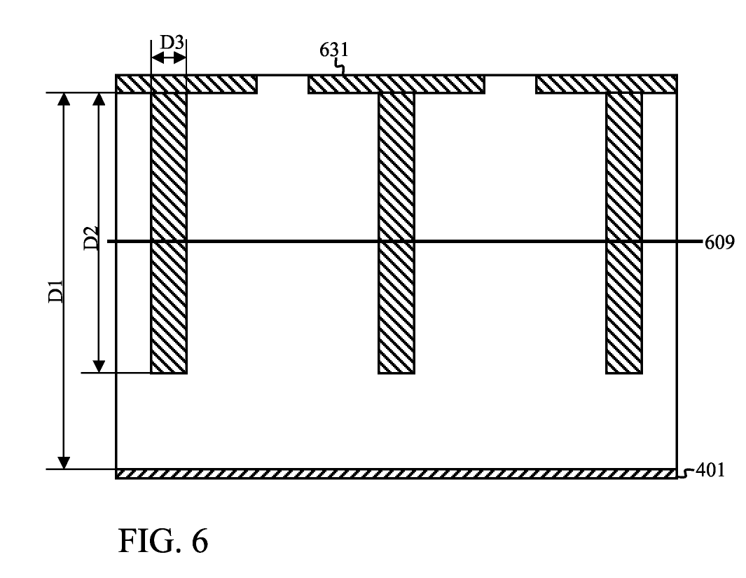

FIG. 6 illustrates a simple APS configuration. The elongated spatial element is depleted by a bias voltage applied between the back layer 401 of first conductivity type and the contact doped region 631 of second conductivity type. In this embodiment the radiation generated secondary charges are collected by the back layer 401 and the signal charges are collected by the depleted spatial elements. Inside the depleted spatial element the signal charges flow vertically to the contact doped region 631. The signal can be read out for instance by a read out chip which can be connected to the contact doped region 631 by bump bonds. Another option is to connect the contact doped region 631 to the gate of an integrated FET. Instead of the contact doped region 631 one can also guide the radiation generated charges collected by the depleted spatial elements to a depleted internal gate structure where the charge can be read using for example an integrated junction field effect transistor (JFET). An integrated floating gate FET can also be used to read the signal charge. In case the substrate is p type and it is essentially fully depleted the electron potential energy on the line 609 is presented by FIG. 5C.

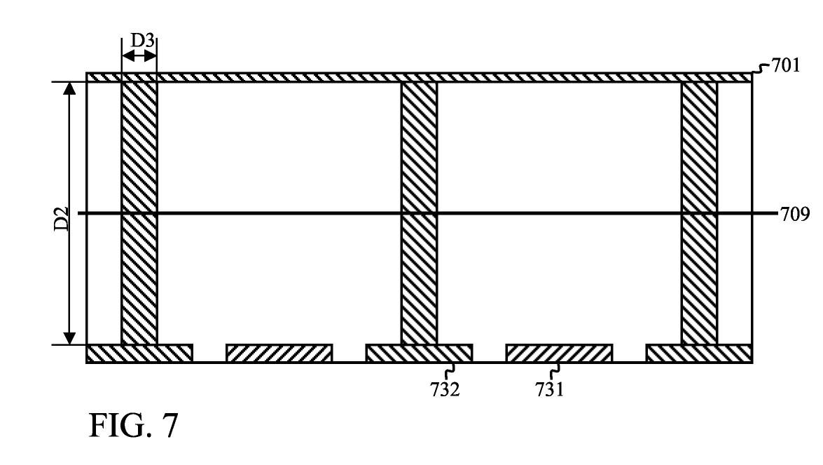

FIG. 7 illustrates another simple APS configuration where the substrate is essentially fully depleted. The heavily doped front layer 701 is of the second conductivity type and the substrate contact doped region 731 is of the first conductivity type. In this embodiment the signal charges are not collected by the fully depleted elongated spatial elements but by the depleted substrate. If the substrate is p type, the electron potential energy on the line 709 is illustrated by FIG. 5C. In this case the signal charges are holes and they are collected by the electron potential energy maxima presented in FIG. 5C. In these maxima the signal charge holes flow vertically to the contact doped regions (731) on the backside of the device. The optional doped region 732 of the second conductivity type which may be completely depleted, floating, or appropriately biased, and which preferably surrounds the substrate contact doped regions (731). The spatial elements may surround the contact doped regions (731) in a honey comb fashion. Instead of using several spatial elements, one can also use a single spatial element surrounding completely the signal charge collecting contact doped doped regions (731). The form of such a spatial element on the horizontal cross-section presented by the line 709 resembles the form of a net. The signal charge can be read for instance by a read out chip connected by bump bonds to the contact doped regions (731) by an integrated FET connected to the contact doped region 731 or the contact doped region 731 can be replaced by an integrated FET comprising an internal gate or a floating gate structure.

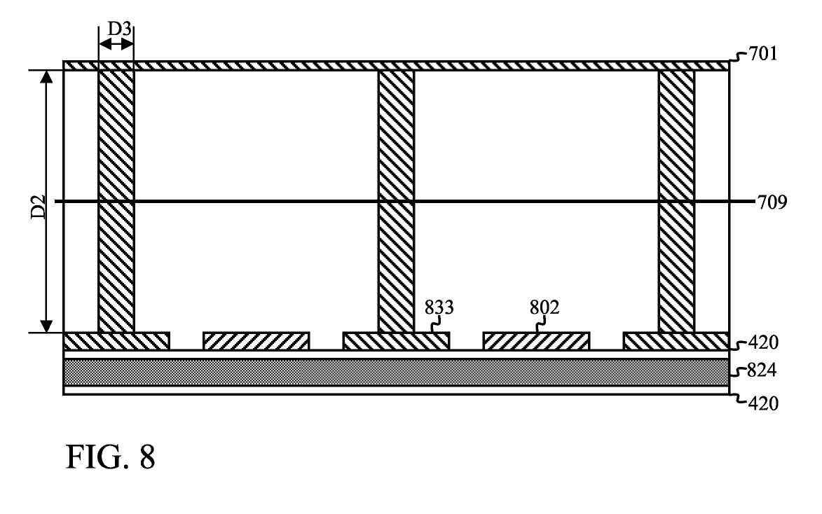

FIG. 8 illustrates a CCD structure having the same operation principle than the structure in FIG. 7, i.e. the signal charges are collected by an essentially fully depleted substrate and the secondary charges are collected by the depleted elongated spatial elements. The signal charges flow to the depleted buried channel layer 802 of the first conductivity type to be transported to the edge of the device where they can be read. The gate 824 is surrounded by an isolator layer 420. The horizontal cross-section of the spatial element can also have the form of a long and thin rectangle. One should note, that if the doping of the front layer 701 were changed to an opposite conductivity type if the doping 833 were used as a buried channel layer and if the doping 802 were used as a channel stop, the structure would correspond to the embodiment presented in FIG. 4.

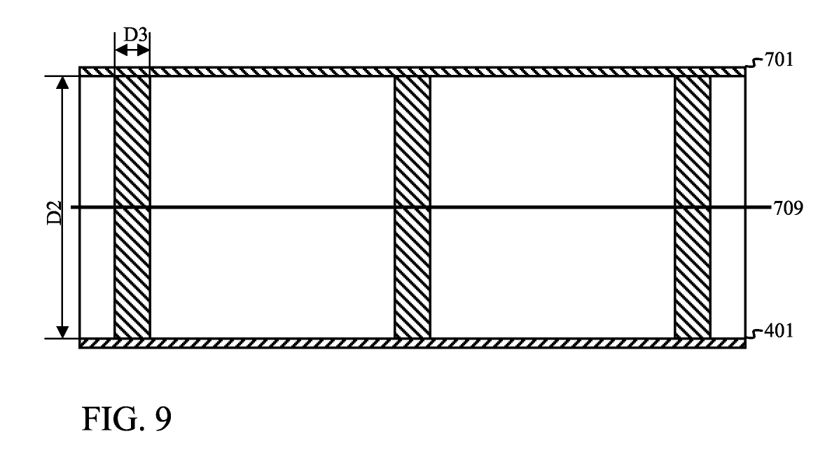

FIG. 9 illustrates a simple diode structure which can be used like a normal pin radiation detection device. A considerably smaller bias voltage is, however, needed to deplete the substrate and the elongated spatial elements than the corresponding pin structure without the spatial elements. If the horizontal dimensions of the spatial elements the distances between the spatial elements and the doping levels of the spatial elements and the substrate are designed properly, the spatial elements and the substrate can be depleted at a very low voltage or even at zero bias voltage.

It should be noted that in the interpretation of the scope of protection the term full depletion is to be understood in relation to reasonable tolerances within the field of technology. The depleted areas of the spatial elements should contain at least 50% of the activated net dopant atoms of the second conductivity type and the possible unwanted neutral areas of the spatial elements should contain less than 50% of the activated net dopant atoms of the second conductivity type. This issue is dealt with in more detail below.

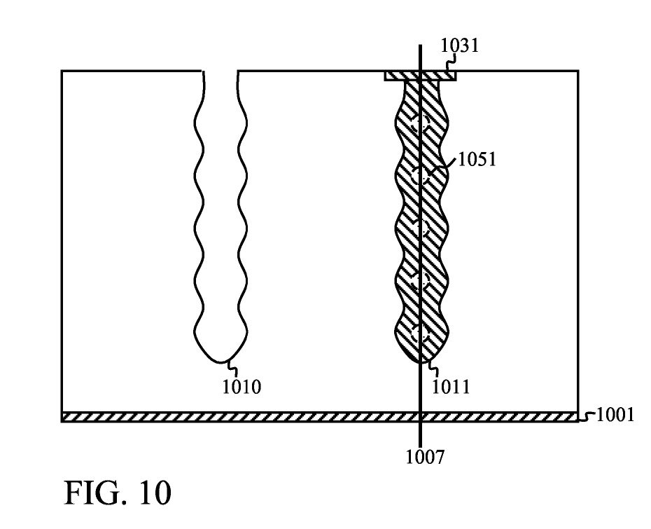

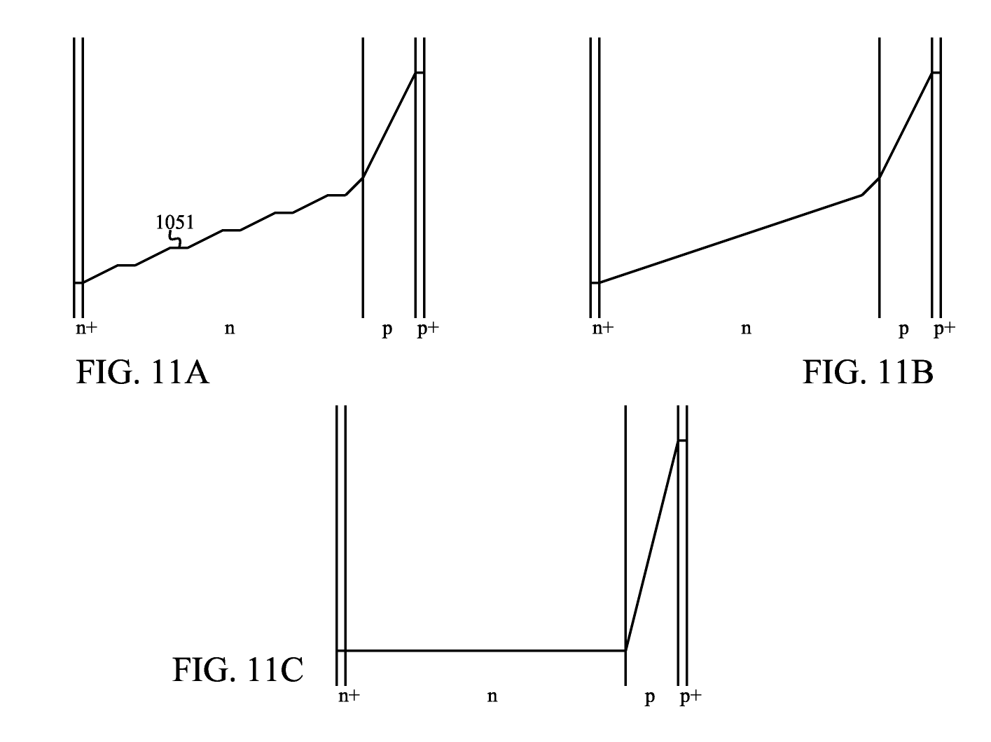

FIG. 10 illustrates a cavity that has been processed in to a semi-conductor substrate of the first conductivity type. The walls of the cavity 1010 are not straight due to a significantly imperfect process. A spatial element 1011 is being formed by filling the cavity with semiconductor material of the second conductivity type. Next a contact doping 1031 of the second conductivity type and a back layer 1001 of the first conductivity type are added to the structure. During operation a suitable reverse bias is applied between the contact doping 1031 and the back layer 1001 in order to deplete the spatial element. However, due to the imperfect processing, neutral parts 1051 exist in the spatial element at the locations where the spatial element is at the thickest. At the locations where the spatial is at the thinnest the spatial is fully depleted.

This can be seen in FIG. 11A where the electron potential function on the line 1007 is shown. In FIGS. 11A, 11B and 11C it is assumed that the first conductivity type is p type and that the second conductivity type is n type. The n+ area corresponds to the contact doping 1031, the n area corresponds to the spatial element 1011, the p area corresponds to the substrate and the p+ area corresponds to the back layer 1001. The heavily doped contact doping 1031 and the back layer 1001 are neutral inside, and thus the electron potential function is a straight horizontal line at these locations. The straight horizontal parts of the electron potential function inside the spatial element correspond to the thick neutral parts of the spatial element. In the fully depleted thin areas of the spatial elements an electron potential gradient exists.

In FIG. 11B a situation is presented where the walls of the spatial element are straight or have only minor deviations. The spatial element is now fully depleted at every location and a potential gradient exists all the way through the spatial element. FIG. 11C represents a situation where a 3D electrode is used instead of the spatial element. The 3D electrode is completely neutral inside, i.e. there is substantially no electric field present inside the 3D electrode. The situations in FIGS. 11A and 11B are very similar. There exists an average vertical potential gradient inside the spatial elements, which is approximately the same in FIGS. 11A and 11B. If the substrate is also fully depleted, there exists a vertical electron potential gradient inside the substrate too.

The situation is completely the opposite in FIG. 11C. There is neither a vertical electron potential gradient inside the 3D electrode nor inside the substrate even if the substrate is fully depleted. The electron potential gradient between the 3D electrode and the back layer is far greater than the electron potential gradient between the spatial element and the back layer, when the voltage between the contact doping and the back layer is the same. The spatial element may touch the heavily doped back layer 1001 (see FIGS. 4, 5 and 7-9). The 3D electrode may, however, not touch or be close to the heavily doped back layer 1001 since this would lead to electric breakdown, i.e. the electric field between the back layer and the 3D electrode would become too high. Only a fraction of the 3D electrode is depleted; typically less than 1% of the activated net dopant atoms inside the 3D electrode are depleted. There exists also a neutral path from the beginning to the end of the 3D electrode, which is not the case in an appropriately biased spatial element.

Even though the walls of the spatial element are straight there may be neutral areas inside an appropriately biased spatial element if the dopant density of the semiconductor material of the second conductivity type forming the spatial element has significant fluctuations. In this case the electron potential profile may resemble the one presented in FIG. 11A. One should note that the neutral areas inside the spatial element are unwanted and result from an imperfect manufacturing process. The neutral areas inside appropriately biased spatial elements affect more the operation of a device where signal charges are of the second conductivity type than of the first conductivity type. For this reason it may be more advantageous to use the latter type of device than the former type of device.

The benefits of the invented structure are not only limited to radiation detection devices. The low depletion voltage of the structure reduces the power consumption of electronic devices which is important in portable devices. On the other hand large depleted areas can be realized in order to reduce capacitances and thus to improve the operation speed of electronics which is important for instance in RF electronics. The low maximal electric field values of the invented structure lead to improved break down characteristics and thus to a increased voltage handling capacity of electronics which is important for example in power electronics.

Depending on the work functions of the substrate semiconductor material and of an associated metal contact, a heavily doped contact region of the same conductivity type than the substrate may be necessary between the metal and the substrate. However, if the work functions of the semiconductor material and the associated contact metal are suitable, these heavily doped contact regions are not necessary. The doped regions 401 and 731 could, for instance, be replaced by a suitable metal contact. A metal contact is also applied to the doped regions 631 and 701 which form a diode structure with the substrate semiconductor material. The doped regions forming the diode can be replaced by a Schottky diode which is formed of a metal contact having an appropriate work function with respect to the semiconductor material. The afore described metal (or more generally conductor) contacts to the doped regions 401, 731 and 631, 701 are not shown in FIGS. 4, 6, 7, 8 and 9, but their application is known to a person skilled in the art.

For a person skilled in the art it is also clear that the design of the spatial element may be adapted to a plurality of requirement without deviating from the scope of the present invention. For instance, the horizontal cross-section may be formed to some other shape than a circle, for example to an oval or to a rounded rectangle. In case when the signal charges are collected by the depleted substrate (FIGS. 7 and 8) the horizontal cross-section of the depleted elongated spatial elements can have the form of a long and thin rectangle or of a net instead of the more point like structures presented in FIG. 3. This applies also to the diode structure presented in FIG. 9. The size of the second horizontal dimension at the first surface 101 may be comparable to the dimension D3 corresponding to the smallest horizontal dimension of the spatial element at the first surface 101 or it may be comparable to the size of the semiconductor chip. The depth of protrusion of the spatial element may be varied according to the implementation throughout the depth of the substrate. Adjacent columns may be identical, as shown in FIGS. 1 and 2 or their design length distance dopant concentration and shape may be varied according to the implementation. The protrusion angle of the spatial element with respect to the front surface can differ from the perpendicular angle presented in the embodiments of FIGS. 1, 2, 4 and 6 to 9. Instead of one, several spatial elements could be incorporated to one pixel. The spatial elements can be situated in any desired configuration on the front surface of the device; for example instead of a hexagonal configuration presented in FIGS. 1 and 2 a square configuration could be used. The dopant concentration of the substrate may be homogenous or it may vary in a predetermined fashion. Spatial elements of the first conductivity type could be added on either side of the structure in order to improve radiation damage tolerance of the structure; such a structure would be resistant to type inversion of the substrate. An important design criteria of the invented structure is that the fields inside the structure should be below the break down field.

The radiation detector devices in FIGS. 4, 6, 7, 8 and 9 represent some different ways to incorporate a device according to the present invention, without limiting the scope of protection to the terms and configurations presented herein. One can combine the structures of the embodiments in various different ways, one can add different doped regions and layers to these structures, one can remove doped regions and layers from these structures, and one can use very different additional structures not presented in this paper. For example, the different structures can also contain heterojunctions between adjacent semiconductor layers. Vertical and horizontal antiblooming structures can be added to the invented structure. The substrate contact can also be on the front side of the structure. Guard structures comprising for instance doped regions, semiconductor insulator conductor structures and Schottky contacts can be added on both the front and back side of the structure. Antireflection coatings scintillator layers and thin metal layers can be incorporated to the structure. The invented structure can be operated in avalanche or in non avalanche mode. The operation principle of the structure can be based on charge integration or on the detection of radiation induced voltage or current pulses. The invented structure can be back or front illuminated and it can be apart of a multichip assembly including for instance memory, read out and microprocessor chips just to mention some possibilities. The different chips can be connected for example by a flip chip technique or by wire bonding.

It will be obvious to a person skilled in the art that, as the technology advances, the inventive concept can be implemented in various ways. The invention and its embodiments are not limited to the examples described above but may vary within the scope of the claims.

1. A semiconductor device, including
a first region of semiconductor material of a first conductivity type having first surface and at a defined first distance from the first surface, a second surface,
an elongated spatial element of semiconductor material of a second conductivity type protruding from the first surface to a second distance into the first region of semiconductor material, the second distance being longer than the smallest dimension of the spatial element at the first surface of the a first region of semiconductor material; and
a bias voltage supply adjusted in operation to, within tolerance, deplete the region of the spatial element from majority carriers of the second conductivity type.

2. A semiconductor device according to claim 1, wherein the second distance is at least two times longer than the smallest dimension of the spatial element at the first surface of the a first region of semiconductor material.

3. A semiconductor device according to claim 1 or 2, wherein the second distance equals the first distance.

4. A semiconductor device according to claim 1, wherein in cross-section region parallel to the first surface of the semiconductor device, and between the first surface and the second distance the amount of dopant atoms of the first conductivity type substantially equals the amount of dopant atoms of the second conductivity type.

5. A semiconductor device according to claim 4, wherein the cross-section region corresponds to one pixel of the semiconductor device.

6. A semiconductor device according to claim 1, wherein the cross-section of the elongated spatial element parallel to the first surface of the semiconductor device, and between the first surface and the second distance decreases with relation to the depth of the protrusion.

7. A semiconductor device according to claim 1, wherein the dopant concentration of the spatial element decreases with relation to the depth of protrusion.

8. A semiconductor device according to claim 1, wherein the dopant concentration of the first region of semiconductor material increases along the first distance.

9. A semiconductor device according to claim 1, wherein the dopant concentration of the semiconductor material of the spatial element is lower than 10¹⁷cm⁻³.

10. A semiconductor device according to claim 1, wherein the elongated spatial elements protrude into the first region of semiconductor material of a first conductivity type perpendicularly with respect to the first surface.

11. A semiconductor device according to claim 1, wherein the second distance is at least 5 μm.

12. A semiconductor device according to claim 1, wherein within tolerance of depletion the depleted region of the spatial element contains at least 50% of the activated net dopant atoms of the second conductivity type of the spatial element.
